(19) United States
(12) Patent Application Publication
(10) Pub. No.: US 2014/0174921 A1
(43) Pub. Date: Jun. 26, 2014

(54) Multi-Piece Target and Magnetron to Prevent Sputtering of Target Backing Materials

(71) Applicant: INTERMOLECULAR, INC., San Jose, CA (US)

(72) Inventors: Hong Sheng Yang, Pleasanton, CA (US); Chi-I Lang, Cupertino, CA (US); ShouQian Shao, Fremont, CA (US)

(73) Assignee: Intermolecular, Inc., San Jose, CA (US)

(21) Appl. No.: 13/725,622

(22) Filed: Dec. 21, 2012

(51) Int. Cl. C23C 14/35

(52) U.S. Cl. CPC C23C 14/351
USPC 204/298.13; 204/298.12

(57) ABSTRACT

An apparatus for sputtering wherein magnets within the magnetron of a sputtering source are positioned such that Ar⁺ ions arriving at the surface of a multi-piece target do not strike the target perpendicular to the surface at the gaps between the sectors of the target. The off-angle bombardment of the Ar⁺ ions ensures that the Ar⁺ ions do not result in the sputtering and deposition of target backing material through the gap between the target sectors.

### TECHNICAL FIELD

One or more embodiments relate to methods and apparatuses for preventing contamination from backing materials during sputtering multi-piece targets.

### BACKGROUND

Physical vapor deposition (PVD) is commonly used within the semiconductor industry as well as within solar, glass coating, and other industries, in order to deposit a layer over a substrate. Sputtering is a common physical vapor deposition method, where atoms or molecules are emitted from a target material by high-energy particle bombardment and then deposited onto the substrate.

In order to identify different materials, evaluate different unit process conditions or parameters, or evaluate different sequencing and integration of processes, and combinations thereof, it may be desirable to be able to process different regions of the substrate differently. This capability, hereinafter called “combinatorial processing,” is generally not available with tools that are designed specifically for conventional full substrate processing. Furthermore, it may be desirable to subject localized regions of the substrate to different processing conditions (e.g., localized deposition) in one step of a sequence followed by subjecting the full substrate to a similar processing condition (e.g., full substrate deposition) in another step.

Sputtering sources use “targets” to supply materials for sputter deposition of thin films. The target material comprises either an element, mixture of elements, alloy, or a compound such as an oxide, nitride, boride, silicide, sulfide, selenide, telluride, or carbide. These materials can be sputtered onto a substrate without chemical change. Alternatively, compounds such as oxides and nitrides can be formed by “reactive” sputtering wherein a reactive gas is mixed with an inert sputtering gas such as argon and reacts with the sputtered material to form the compound. For example, a metal oxide or metal nitride layer can be formed by sputtering metal in the presence of oxygen or nitrogen onto a substrate. Targets for sputtering can also be made from metal alloys and other mixtures of more than one material in order to form layers having mixed composition. Such targets are readily available from suppliers both as stock items and by custom order for unique mixture requirements.

“Multi-piece” sputtering targets are also known and available from suppliers. A multi-piece sputtering target comprises more than one separate area or sector of the target rather than being a single piece of material. The sectors may be formed from the same material or may have different compositions. Multi-piece sputtering targets have generally been used as one method of providing two materials such as two metals from a single target, or have been used to form large targets for depositing coatings over large areas.

A typical sputtering source uses a plasma that impinges on a large area of the target and provides a source of material from all areas of the target at once. There can be variability in relative composition of sputtered material when using a multi-piece sputtering target, but, in most cases, this variability is undesirable because a fixed composition of sputtered material is required for most applications. Further, without intervention, material can be sputtered from the target backing material through the gaps between the target segments leading to contamination of the deposited layer. This is more prevalent as the target nears its end of life.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, magnets within the magnetron of a sputtering source are positioned such that Ar⁺ ions arriving at the surface of a multi-piece target do not strike the target perpendicular to the surface at the gaps between the sectors of the target. The off-angle bombardment of the Ar⁺ ions ensures that the Ar⁺ ions do not result in the sputtering and deposition of target backing material through the gap between the target sectors.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic diagram for implementing combinatorial processing and evaluation according to some embodiments.

FIG. 2 is a schematic diagram for illustrating various process sequences using combinatorial processing and evaluation according to some embodiments.

FIG. 3 shows an illustrative embodiment of a multi-chambered processing system according to some embodiments.

FIG. 4 shows an illustrative embodiment of a multi-source sputtering system according to some embodiments.

FIG. 5 shows an illustrative embodiment of a multi-source sputtering system according to some embodiments.

FIG. 6 shows an illustrative embodiment of a multi-chambered processing system according to some embodiments.

FIG. 7 is a schematic diagram illustrating the exploitation of the horizontal component of the Lorentz force to facilitate off-angle Ar⁺ ion bombardment according to some embodiments.

FIG. 8 is a schematic diagram for illustrating an example of a magnet configuration according to some embodiments according to some embodiments.

FIG. 9 is a schematic diagram for illustrating an example of a magnet configuration according to some embodiments according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Before the present invention is described in detail, it is to be understood that unless otherwise indicated this invention is not limited to specific layer compositions or surface treatments. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The term “about” generally refers to ±10% of a stated value.

The term “site-isolated” as used herein refers to providing distinct processing conditions, such as controlled temperature, flow rates, time of processing, composition of material emitted from a sputtering source, and the like. Site isolation may provide complete isolation between regions or relative isolation between regions. Preferably, the relative isolation is sufficient to provide a control over processing conditions within ±10%, within ±5%, within ±2%, within ±1%, or within ±0.1% of the intended conditions. Where one region is processed at a time, adjacent regions are generally protected from any exposure that would alter the substrate surface in a measurable way.

The term “site isolated region” is used herein to refer to a localized area on a substrate which is, was, or is intended to be used for processing or formation of a selected material made by processing conditions that are distinct from one site-isolated region to another. The site-isolated region can include one region and/or a series of regular or periodic regions predefined on the substrate. The site-isolated region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein. Wafer shapes and sizes can vary and include commonly used round wafers of 2″, 4″, 200 mm, or 300 mm in diameter.

The term “magnetron” as used herein refers to a magnet assembly used to control the flow of electrons and/or ions in a sputtering source. The magnet assembly can be either a permanent magnet or an electromagnet. The magnet assembly can be stationary or can be moveable (e.g. rotatable).

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

Embodiments of the present invention provide multi-piece sputtering targets for use in combinatorial processing. The multi-piece sputtering targets can be used with apparatuses and methods disclosed in U.S. patent application Ser. No. 13/339,648, filed on Dec. 29, 2011, for systematic exploration of deposition process variables in a combinatorial manner, with the possibility of performing many process variations on a single substrate. The high deposition rate combinatorial processing along with the use of a multi-piece sputtering target permits efficient use of target materials to optimize process conditions and design of novel materials.

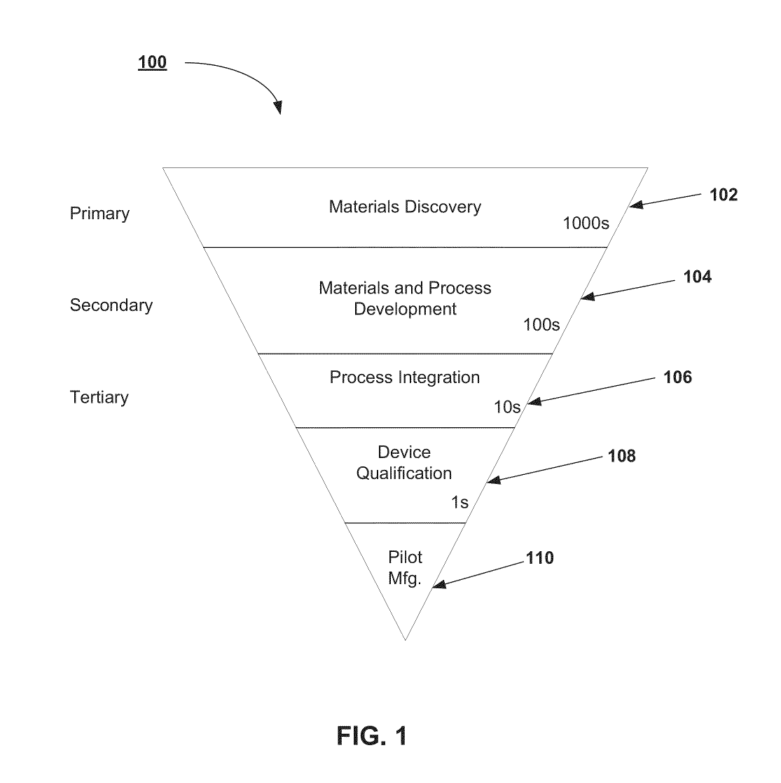

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention.

While the combinatorial processing varies certain materials, hardware details, or process sequences, the composition or thickness of the layers or structures or the actions, such as cleaning, surface preparation, deposition, surface treatment, etc. is substantially uniform through each discrete site-isolated region. Furthermore, while different materials or processes may be used for corresponding layers or steps in the formation of a structure in different regions of the substrate during the combinatorial processing, the application of each layer or use of a given process is substantially consistent or uniform throughout the different regions in which it is intentionally applied. Thus, the processing is uniform within a region (inter-region uniformity) and between regions (intra-region uniformity), as desired. It should be noted that the process can be varied between site-isolated regions, for example, where a thickness of a layer is varied or a material may be varied between the regions, etc., as desired by the design of the experiment.

The result is a series of site-isolated regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each site-isolated region are designed to enable valid statistical analysis of the test results within each region and across regions to be performed.

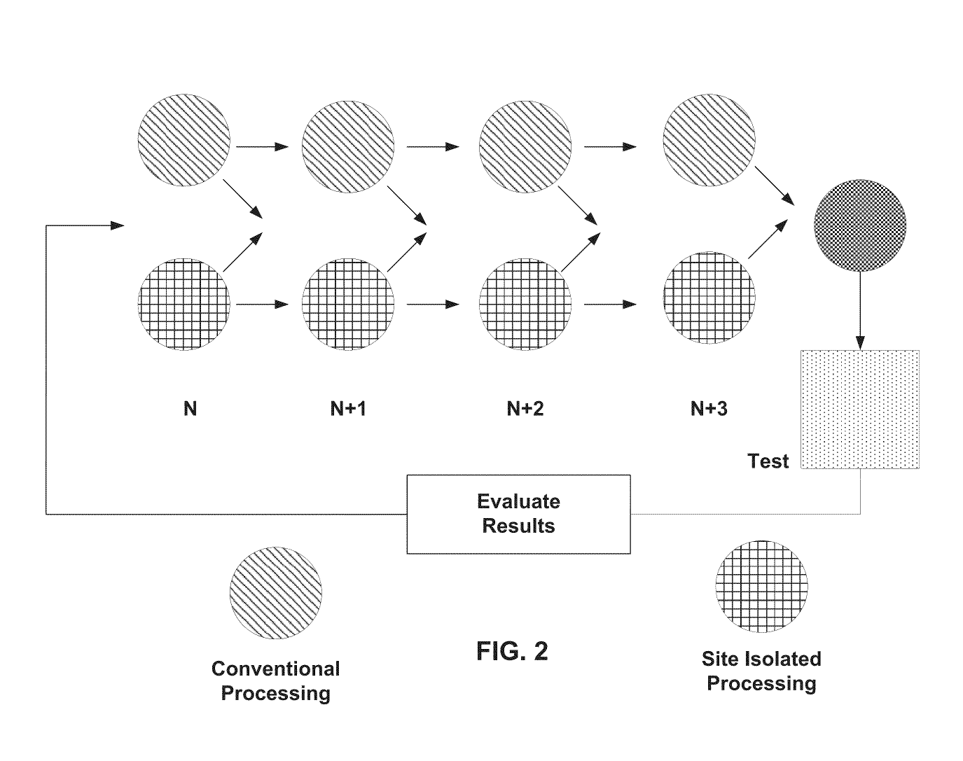

FIG. 2 is a simplified schematic diagram illustrating a general methodology for combinatorial process sequence integration that includes site-isolated processing and/or conventional processing in accordance with one embodiment of the invention. In one embodiment, the substrate is initially processed using conventional process N. In one exemplary embodiment, the substrate is then processed using site-isolated process N+1. During site-isolated processing, an HPC module may be used, such as the HPC module described in U.S. patent application Ser. No. 11/352,077, filed on Feb. 10, 2006. The substrate can then be processed using site-isolated process N+2, and thereafter processed using conventional process N+3. Testing is performed and the results are evaluated. The testing can include physical, chemical, acoustic, magnetic, electrical, optical, etc. tests. From this evaluation, a particular process from the various site-isolated processes (e.g. from steps N+1 and N+2) may be selected and fixed so that additional combinatorial process sequence integration may be performed using site-isolated processing for either process N or N+3. For example, a next process sequence can include processing the substrate using site-isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above process flows can be applied to entire monolithic substrates, or portions of the monolithic substrates.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, the order in which materials are deposited, hardware details of the gas distribution assembly, etc. It should be appreciated that these process parameters are exemplary and not meant to be an exhaustive list as other process parameters commonly used with remote plasma exposure systems may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Some embodiments provide sputtering sources with multi-piece sputtering targets for use in PVD-based combinatorial processing, with the possibility of performing many process variations on a single substrate. The multi-piece sputtering targets can also be used with conventional PVD apparatuses using conventional sputtering methods, or can be used with apparatuses and methods disclosed in co-owned U.S. patent application Ser. No. 13/339,648, for systematic exploration of deposition process variables in a combinatorial manner. High deposition rate combinatorial processing along with the use of a multi-piece sputtering target permits efficient use of resources and materials to optimize process conditions and design of novel materials. In the '648 application, a high deposition rate of sputtering is provided by locating the sputtering source much closer to the substrate than is practiced in prior art deposition methods, and by orienting the sputtering sources normal to the substrate, rather than tilting the sputtering source as is common in prior art deposition apparatuses. The multi-piece sputtering targets can also be used with the high ionization sputtering gun described in co-owned U.S. patent application Ser. No. 13/281,316.

Some embodiments provide apparatuses that utilize sputtering from a multi-piece sputtering target for depositing layers onto a substrate and that have the capability of depositing layers in a combinatorial manner. Accordingly, a sputtering source is provided comprising a device capable of causing the emission of material from a target (e.g., a cathode), and a multi-piece sputtering target comprising a first sector and a second sector. Although two sectors are discussed, those skilled in the art will understand that the target may be formed from any number of sectors. The composition of the material may be the same in the two sectors or may be different in the two sectors. In some embodiments, the selection mechanism can comprise a movable magnetron which can be positioned to sputter material selectively from the first sector, the second sector, or a combination thereof, (e.g., material can be emitted from both sectors in any desired combination to produce a particular composition comprising the component materials present in the first and second sectors).

Some embodiments further include apparatuses for performing physical vapor deposition. Some embodiments of the apparatuses can comprise a process chamber; one or more sputtering sources disposed within the process chamber; a substrate support disposed within the process chamber, the substrate support operable to support a substrate; a shield positioned between the sputtering source and the substrate, the shield comprising a substrate aperture positioned under the sputtering source, and a transport system integrated with the substrate support, wherein the transport system is capable of positioning the substrate such that one of a plurality of site isolated regions on the substrate can be exposed to sputtered material through the substrate aperture positioned under each of the sputtering sources. The sputtering source can comprise a multi-piece sputtering target.

The process chamber provides a controlled atmosphere (referred to as a “sputtering atmosphere”) such that sputtering can be performed at any gas pressure or gas composition necessary to perform the desired combinatorial processing. The sputtering atmosphere parameters include total pressure, gas composition, gas flow rate, reactive gas composition, reactive gas flow rate, or combinations thereof. The reactive gas flow rate can be greater than or equal to zero. The sputtering atmosphere typically comprises one or more inert gases such as neon, argon, krypton, or xenon. In some embodiments, the sputtering atmosphere further comprises one or more reactive gases such as oxygen, hydrogen, or nitrogen. Additional gases can be used as desired for particular applications.

In some embodiments, the sputtering source is oriented substantially normal to the substrate, and can be placed in close proximity, such that the target is located from about 20 to about 100 mm from the substrate. In some embodiments, the apparatuses can further comprise two more sputtering sources. In some embodiments, the apparatuses can comprise a substrate aperture for each sputtering source, wherein a substrate aperture is positioned between each sputtering source and the substrate. In some embodiments, the apparatuses can further comprise an aperture shutter, wherein the aperture shutter is moveably disposed over the substrate aperture. The substrate aperture typically has an opening smaller than the substrate so that discrete regions of the substrate can be subjected to distinct process parameters in a combinatorial manner. However, there is no particular limit on the size of the substrate aperture.

The substrate parameters comprise substrate temperature, substrate bias, or combinations thereof. Accordingly, in some embodiments, the apparatuses comprise a substrate support capable of providing independent substrate temperature control up to 500 C, and applying a bias voltage of up to −300 V.

Substrates can be a conventional round 200 mm, 300 mm, or any other larger or smaller substrate/wafer size. In some embodiments, substrates may be square, rectangular, or other shape (e.g. for glass coating applications). One skilled in the art will appreciate that substrate may be a blanket substrate, a coupon (e.g., partial wafer), or even a patterned substrate having predefined regions. In some embodiments, a substrate may have regions defined through the processing described herein.

Some embodiments further include methods of forming a layer on a substrate using sputtering sources comprising multi-piece sputtering targets. The methods can be utilized with conventional processing or with combinatorial processing. The methods can comprise exposing a first site-isolated region of a surface of a substrate to material from a sputtering source using a first set of process parameters, exposing a second site-isolated region of the surface of the substrate to material from the sputtering source using a second set of process parameters, and varying the first and second set of process parameters in a combinatorial manner. During exposure of the surface of the substrate to the sputtering source, the remaining area of the substrate is not exposed to the material from the sputtering target, enabling site-isolated deposition of sputtered material onto the substrate. The methods can further comprise exposing three or more site isolated regions of the substrate to material from the sputtering source using distinct sets of process parameters. There is no particular limit on the number of site isolated regions that can be exposed to distinct processing parameters, and the method is limited only by the size of the substrate chosen and the size of the site isolated region selected for testing. If necessary, additional substrates can be utilized in order to test a full complement of particular combinatorial process parameters.

Those having skill in the art will recognize that the control of layer composition on a substrate can be performed using the multi-piece sputtering targets with the sputtering sources and apparatuses described herein. The composition of layers can be affected by the composition of each sector on the sputtering target (expressible as weight percent, atomic percent, or volume percent), the relative amount of material provided to a substrate from each sector of the sputtering target, as well as the relative sputtering efficiency of different elements and compounds.

In some embodiments, the process parameters can comprise one or more sputtering parameters, sputtering atmosphere parameters, substrate parameters, or combinations thereof. The process parameters can be varied such that each combination of sputtering parameters, sputtering atmosphere parameters, and substrate parameters can be tested independently. The sputtering parameters comprise, exposure times, power, composition of material emitted from the sputtering source, target-to-substrate spacing, or combinations thereof. The sputtering atmosphere parameters comprise total pressure, gas composition, gas flow rate, reactive gas composition, reactive gas flow rate, or combinations thereof; wherein the reactive gas flow rate is greater than or equal to zero. The substrate parameters comprise substrate material, surface condition, substrate temperature, substrate bias, or combinations thereof. In some embodiments, the plurality of site isolated regions on the substrate can be exposed to sputtered material using a set of process parameters that can be varied in a combinatorial manner. The process parameters can comprise the same parameters listed above. The process parameters can be varied such that each combination of sputtering parameters and substrate parameters can be tested independently.

In some embodiments, the sputtering source comprises a multi-piece sputtering target comprising a first sector, and a second sector. The composition of the target may be the same or different in the sectors of the target. The composition of emitted material from the sputtering source can then comprise a range of compositions from 0% to 100% of the first composition, from 0% to 100% of the second composition. The percent composition is used in the conventional sense, such that the relative compositions add up to a total of 100%. The relative composition can be specified by any convenient measure, such as atom percent, weight percent or volume percent.

In some embodiments, one sector is used at a time so that emitted material is provided from a single sector. Different sectors can be used to provide varying compositions for different layers on a substrate. In some embodiments, the selection mechanism can be configured so that emitted material is provided from portions of two or more sectors to produce layers having mixed compositions including material from more than one sector on the sputtering target.

In some embodiments, the methods can comprise forming layers on a substrate using an apparatus comprising two or more sputtering sources. In some embodiments, the methods can further comprise depositing additional layers onto any site-isolated region to build multi-layered structures if desired. In this manner, a plurality of process parameters to deposit one or a plurality of layers can be explored on a single substrate using distinct process parameters. If desired, combinatorial processing can be utilized to prepare layers having distinct compositions.

Software is provided to control the process parameters for each substrate for the combinatorial processing. Examples of process parameters that can be controlled by software include one or more sputtering parameters, sputtering atmosphere parameters, substrate parameters, or combinations thereof. The process parameters can be varied such that each combination of sputtering parameters and substrate parameters can be tested independently. The sputtering parameters comprise, exposure times, power, composition of material emitted from the sputtering source, target-to-substrate spacing, or combinations thereof. The sputtering atmosphere parameters comprise total pressure, gas composition, gas flow rate, reactive gas composition, reactive gas flow rate, or combinations thereof; wherein the reactive gas flow rate is greater than or equal to zero. The substrate parameters comprise substrate material, surface condition, substrate temperature, substrate bias, or combinations thereof.

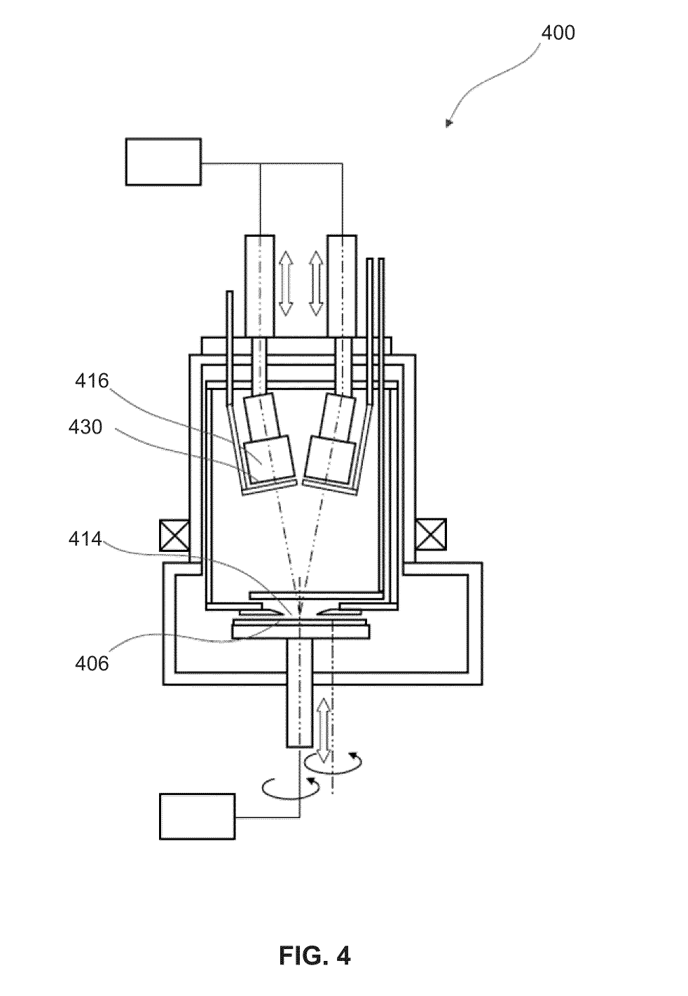

Embodiments are provided in FIGS. 4-6 with an orientation having sputtering sources disposed above substrates, with optional substrate apertures, selection apertures, and shutters disposed between the sputtering sources and substrates, and having magnetrons disposed above sputtering targets. The common orientation shown in these figures is solely for illustration and is not meant to imply an orientation relative to gravity. Those having skill in the art will recognize that the sputtering sources can be positioned in any orientation relative to the substrate.

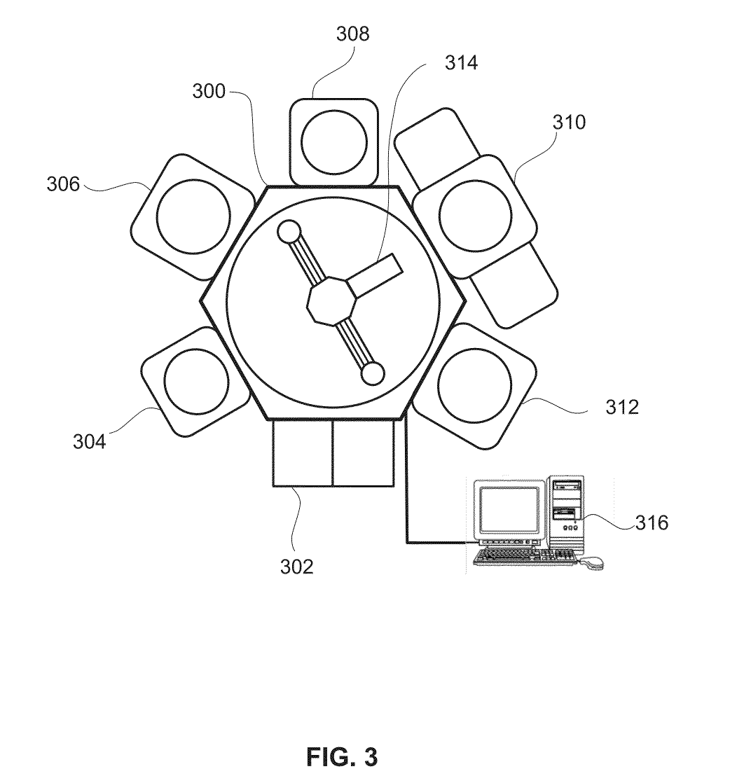

FIG. 3 is a simplified schematic diagram illustrating an integrated high productivity combinatorial (HPC) system in accordance with some embodiments. The HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. No. 11/672,478 filed Feb. 7, 2007, now U.S. Pat. No. 7,867,904 and claiming priority to U.S. Provisional Application No. 60/832,248 filed on Jul. 19, 2006, and U.S. application Ser. No. 11/672,473, filed Feb. 7, 2007 and claiming priority to U.S. Provisional Application No. 60/832,248 filed on Jul. 19, 2006, which are all herein incorporated by reference. With HPC system, a plurality of methods may be employed to deposit material upon a substrate employing combinatorial processes.

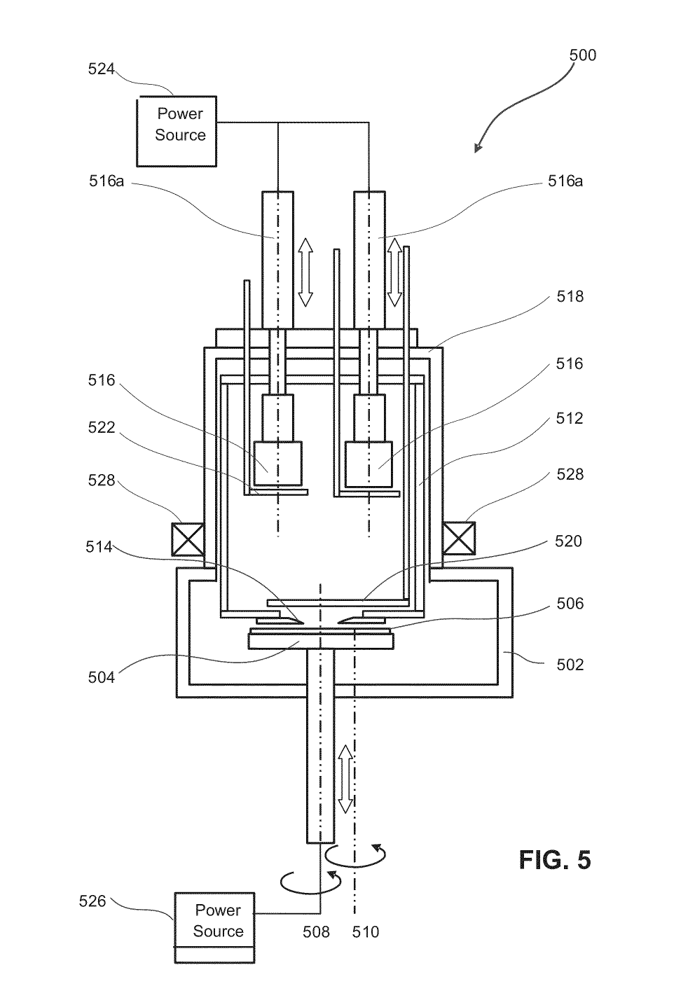

FIG. 4 is a simplified schematic diagram illustrating some embodiments of the present invention. A sputter chamber 400 is configured to perform combinatorial processing using a plurality of sputtering sources each having a sputtering source comprising a multi-piece sputtering target as described previously. A plurality of sputtering sources 416 with multi-piece sputtering targets 430 are shown positioned at an angle so that they can be aimed through a single substrate aperture 414 to a site-isolated region on a substrate 406. The sputtering sources 416 are positioned such that the target is at least about 80 mm from the substrate 406 to ensure uniform flux to the substrate within the site-isolated region. Typically the target is positioned from about 80 mm to about 300 mm from the substrate. Additional components shown are similar to components in the illustrative embodiment shown in FIG. 5.

FIG. 5 is a simplified schematic diagram illustrating a sputter chamber configured to perform combinatorial processing and full substrate processing in accordance with some embodiments of the invention. Processing chamber, 500, includes a bottom chamber portion, 502, disposed under top chamber portion, 518. Within bottom portion, 502, substrate support, 504, is configured to hold a substrate, 506, disposed thereon and can be any known substrate support, including but not limited to a vacuum chuck, electrostatic chuck or other known mechanisms. Substrate support, 504, is capable of both rotating around its own central axis, 508 (referred to as “rotation” axis), and rotating around an exterior axis, 510, (referred to as “revolution” axis). Such dual rotary substrate support is central to combinatorial processing using site-isolated mechanisms. Other substrate supports, such as an XY table, can also be used for site-isolated deposition. In addition, substrate support, 504, may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source, 526, provides a bias power to substrate support, 504, and substrate, 506, and produces a negative bias voltage on substrate, 506. In some embodiments power source, 526, provides a radio frequency (RF) power sufficient to take advantage of the high metal ionization to improve step coverage of vias and trenches of patterned wafers. In some embodiments, the RF power supplied by power source, 526, is pulsed and synchronized with the pulsed power from power source, 524.

Substrate, 506, may be a conventional round 200 mm, 300 mm, or any other larger or smaller substrate/wafer size. In some embodiments, substrate, 506, may be a square, rectangular, or other shaped substrate. One skilled in the art will appreciate that substrate, 506, may be a blanket substrate, a coupon (e.g., partial wafer), or even a patterned substrate having predefined regions. In some embodiments, substrate, 506, may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion, 518, of chamber, 500, in FIG. 5 includes process kit shield, 512, which defines a confinement region over a radial portion of substrate, 506. Process kit shield, 512, is a sleeve having a base (optionally integrated with the shield) and an optional top within chamber, 500, that may be used to confine a plasma generated therein. The generated plasma will dislodge atoms from a target and the sputtered atoms will deposit on an exposed surface of substrate, 506, to combinatorial process regions of the substrate in some embodiments. In another embodiment, full wafer processing can be achieved by optimizing gun tilt angle and target-to-substrate spacing, and by using multiple process guns, 516. Process kit shield, 512, is capable of being moved in and out of chamber, 500, (i.e., the process kit shield is a replaceable insert). In another embodiment, process kit shield, 512, remains in the chamber for both the full substrate and combinatorial processing. Process kit shield, 512, includes an optional top portion, sidewalls and a base. In some embodiments, process kit shield, 512, is configured in a cylindrical shape, however, the process kit shield may be any suitable shape and is not limited to a cylindrical shape.

The base of process kit shield, 512, includes an aperture, 514, through which a surface of substrate, 506, is exposed for deposition or some other suitable semiconductor processing operations. Aperture shutter, 520, which is moveably disposed over the base of process kit shield, 512. Aperture shutter, 520, may slide across a bottom surface of the base of process kit shield, 512, in order to cover or expose aperture, 514, in some embodiments. In another embodiment, aperture shutter, 520, is controlled through an arm extension which moves the aperture shutter to expose or cover aperture, 514. It should be noted that although a single aperture is illustrated, multiple apertures may be included. Each aperture may be associated with a dedicated aperture shutter or an aperture shutter can be configured to cover more than one aperture simultaneously or separately. Alternatively, aperture, 514, may be a larger opening and aperture shutter, 520, may extend with that opening to either completely cover the aperture or place one or more fixed apertures within that opening for processing the defined regions. The dual rotary substrate support, 504, is central to the site-isolated mechanism, and allows any location of the substrate or wafer to be placed under the aperture, 514. Hence, the site-isolated deposition is possible at any location on the wafer/substrate.

A gun shutter, 522, may be included. Gun shutter, 522, functions to seal off a deposition gun when the deposition gun may not be used for the processing in some embodiments. For example, two process guns, 516, are illustrated in FIG. 5. Process guns, 516, are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter, 522, can be transitioned to cover and isolate the lifted process guns from the processing area defined within process kit shield, 512. In this manner, the process guns are isolated from certain processes when desired. It should be appreciated that gun shutter, 522, may be integrated with the top of the process kit shield, 512, to cover the opening as the process gun is lifted or individual gun shutter, 522, can be used for each target. In some embodiments, process guns, 516, are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion, 518, of chamber, 500, of FIG. 5 includes sidewalls and a top plate which house process kit shield, 512. Arm extensions, 516a, which are fixed to process guns, 516, may be attached to a suitable drive, (i.e., lead screw, worm gear, etc.), configured to vertically move process guns, 516, toward or away from a top plate of top chamber portion, 518. Arm extensions, 516a, may be pivotally affixed to process guns, 516, to enable the process guns to tilt relative to a vertical axis. In some embodiments, process guns, 516, tilt toward aperture, 514, when performing combinatorial processing and tilt toward a periphery of the substrate being processed when performing full substrate processing. It should be appreciated that process guns, 516, may tilt away from aperture, 514, when performing combinatorial processing in another embodiment. In yet another embodiment, arm extensions, 516a, are attached to a bellows that allows for the vertical movement and tilting of process guns, 516. Arm extensions, 516a, enable movement with four degrees of freedom in some embodiments. Where process kit shield, 512, is utilized, the aperture openings are configured to accommodate the tilting of the process guns. The amount of tilting of the process guns may be dependent on the process being performed in some embodiments.

Power source, 524, provides power for sputter guns, 516, whereas power source, 526, provides RF bias power to an electrostatic chuck. Power source, 524, is operable to produce ions used in the sputtering process. As mentioned above, the output of power source, 526, is synchronized with the output of power source, 524. It should be appreciated that power source, 524, may output a direct current (DC) power supply or a radio frequency (RF) power supply. In another embodiment the DC power is pulsed and the duty cycle is less than 30% on-time at maximum power in order to achieve a peak power of 10-15 kilowatts. Thus, the peak power for high metal ionization and high density plasma is achieved at a relatively low average power which will not cause any target overheating/cracking issues. It should be appreciated that the duty cycle and peak power levels are exemplary and not meant to be limiting as other ranges are possible and may be dependent on the material and/or process being performed.

Chamber 500 includes magnet 528 disposed around an external periphery of the chamber. Magnet 528 is located in a region defined between the bottom surface of sputter sources 516 and a top surface of substrate 506. Magnet 528 may be either a permanent magnet or an electromagnet. It should be appreciated that magnet 528 is utilized to improve ion guidance as the magnetic field distribution above substrate 506 is re-distributed or optimized to guide metal ions onto the substrate.

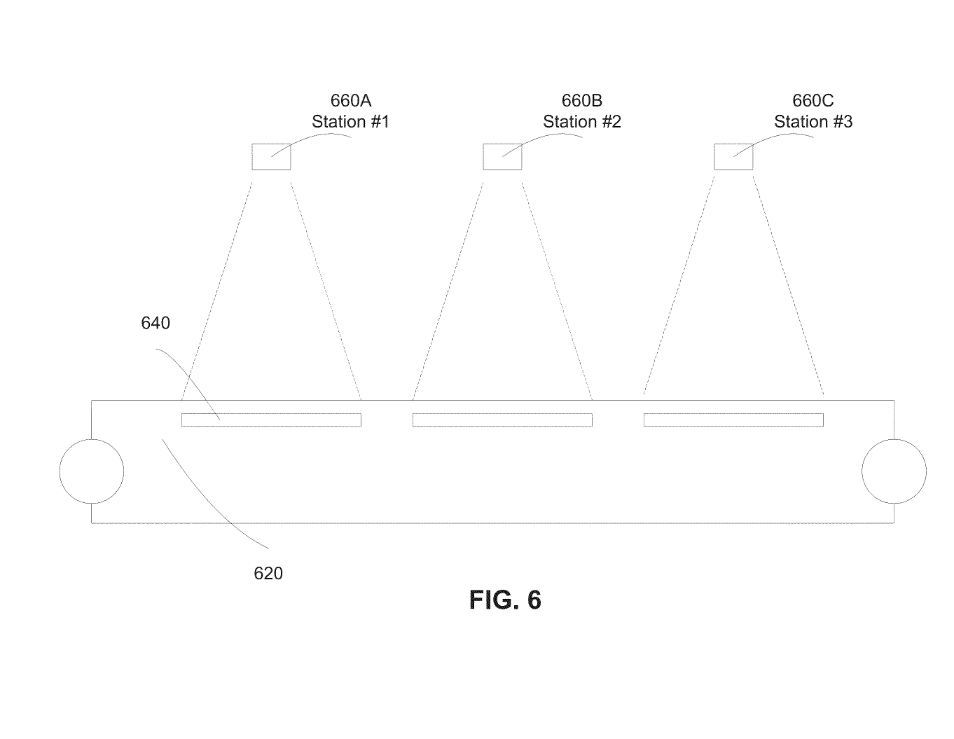

FIG. 6 illustrates an exemplary in-line deposition (e.g. sputtering) system according to some embodiments. This configuration of a sputtering system is particularly well suited for applications such as glass coating, solar panels, display panels, etc. FIG. 6 illustrates a system with three deposition stations, but those skilled in the art will understand that any number of deposition stations can be supplied in the system. For example, the three deposition stations illustrated in FIG. 6 can be repeated and provide systems with 6, 9, 12, etc. stations, limited only by the desired layer deposition sequence and the throughput of the system. In these systems, it is common to employ large, multi-piece, rotating targets to deposit the materials. A transport mechanism 620, such as a conveyor belt or a plurality of rollers, can transfer substrate 640 between different deposition stations. For example, the substrate can be positioned at station #1, comprising a target assembly 660A, then transferred to station #2, comprising target assembly 660B, and then transferred to station #3, comprising target assembly 660C. Station #1 can be configured to deposit a first material. Station #2 can be configured to deposit a second material. Station #3 can be configured to deposit yet a third material.

Although only single target is illustrated in FIG. 6, in some embodiments, a deposition station may include more than one target to allow the co-sputtering of more than one material as discussed previously. Multi-target stations allow the co-sputtering of In with another metal to reduce the In agglomeration and improve the surface roughness as discussed previously.

Embodiments of the present invention can be practiced using any configuration of sputtering sources such as the embodiments illustrated in FIGS. 4-6. Additional process control can be provided by use of a multi-piece target. A multi-piece sputtering target comprises sectors (areas) on a sputtering target of distinct physical sectors of the target. Two or more distinct material compositions can be provided, or the sectors may be made of the same material. An example of a multi-piece target is described in co-owned U.S. patent application Ser. No. 13/444,100, filed on Apr. 11, 2012, which is herein incorporated by reference for all purposes. In some embodiments, the distinct compositions can be pure materials such as pure metals. In other embodiments, the distinct compositions are themselves alloys, compounds, or mixtures comprising a plurality of elements. The material composition in a sector is generally uniform through the thickness of the multi-piece sputtering target such that as material is consumed (used) by sputtering, the composition of each sector remains constant.

The sectors of a multi-piece sputtering target can be of any convenient shape, and the number of sectors and the number of distinct sectors can vary. For example, sectors can comprise pie-shaped sectors, a set of annular rings, square tiles, or hexagonal tiles. The multi-piece sputtering target can comprise any number of distinct sectors limited only by practicality and convenience, and can comprise, for example, two distinct sectors, three distinct sectors, four distinct sectors, ten distinct sectors, and the like.

Mixed compositions within a sector on a multi-piece sputtering target can be provided using any convenient assembly method compatible with the materials to be used. For example, in some embodiments, pluralities of metals can be alloyed, and a region on a multi-piece sputtering target can comprise a uniform alloy. In some embodiments, a plurality of materials can be formed into particles, mixed, and then sintered to form a sector on a multi-piece sputtering target.

The multi-piece sputtering target composition is not limited to any particular materials, and can comprise any sputterable material. In some embodiments, a sector of the multi-piece sputtering target comprises an element such as a metal or semiconductor, or a compound such as an oxide, nitride, oxynitride, silicide, boride, sulfide, selenide, telluride, or carbide of a metal or semiconductor. Mixtures of these compounds can also be provided.

Those skilled in the art will understand that the Ar⁺ ions will participating in the sputtering process will move along trajectories influenced by the Lorentz force as given by Eqn. 1, where F is the total resultant force experienced by the Ar⁺ ion (F is a vector quantity), E is the electric field (E is a vector quantity), v is the velocity of the Ar⁺ ion (v is a vector quantity), and B is the magnetic field (B is a vector quantity).

F=q(E+v×B) Eqn. 1

Generally, the cross-product of v and the B field imparts a lateral component to the resultant force that is parallel to the target surface. Therefore, the Ar⁺ ions impact the target surface in an “off-angle” manner (e.g. at an angle not perpendicular to the surface).

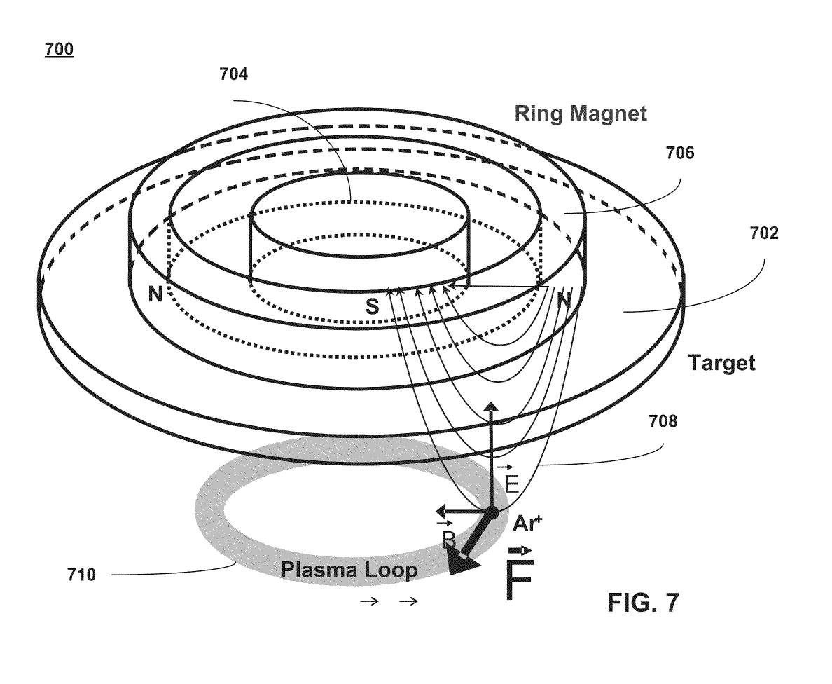

FIG. 7 is a schematic diagram illustrating the exploitation of the horizontal component of the Lorentz force to facilitate off-angle Ar⁺ ion bombardment according to some embodiments. The diagram, 700, includes a target, 702, and a magnet assembly consisting of S-pole, 704, and N-pole, 706. Permanent magnets having a ring shape have been illustrated in FIG. 7. However, those skilled in the art will understand that any suitable arrangement of permanent magnets may be used. Furthermore, those skilled in the art will understand that electromagnets may also be used. To aid in the visualization, magnetic field lines, 708, have been indicated. Additionally, to aid in the visualization the plasma loop formed by the helical trajectories of the electrons in the plasma is also indicated, 710. The electric field (i.e. E) is formed between the substrate (not shown) and the target surface. Generally, the electric field is perpendicular to the target surface. The resultant force, F, acting on an Ar⁺ ion is illustrated resulting from the interaction of the ion with the electric field, E, and the magnetic field, B. Those skilled in the art will understand that at the inflection points of the magnetic field lines, the magnetic field will have the greatest lateral component (i.e. parallel to the target surface) as illustrated. This inflection point will be at the midpoint between the two poles of the magnets. In contrast, the magnetic field will have the smallest lateral component (i.e. perpendicular to the target surface) in regions directly under the poles of the magnets where the magnetic field lines are perpendicular to the target surface.

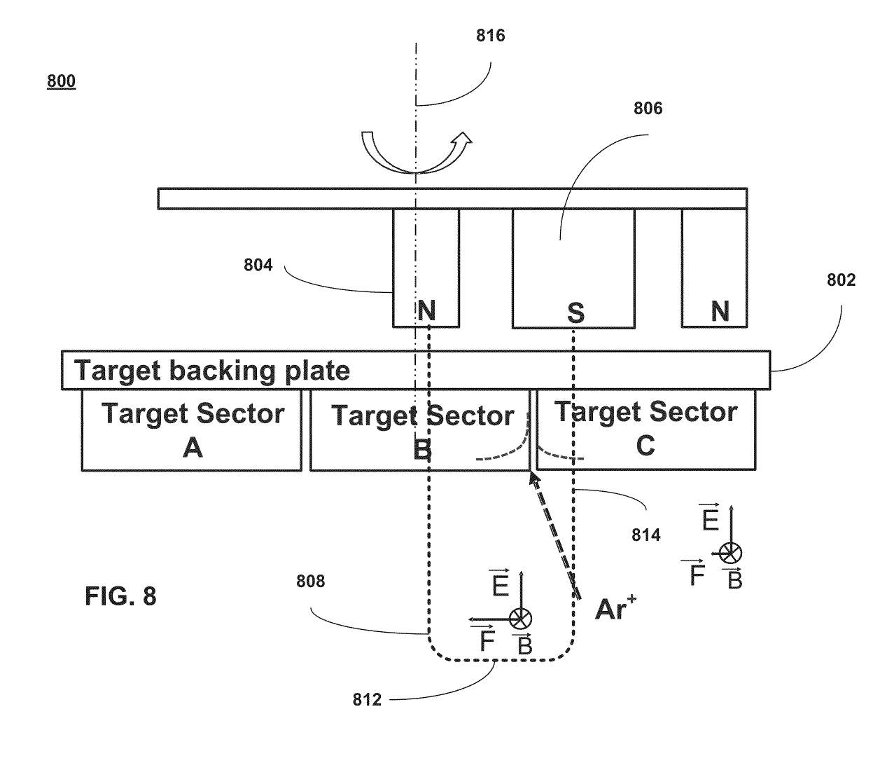

FIG. 8 is a schematic diagram illustrating the exploitation of the horizontal component of the Lorentz force to facilitate off-angle Ar⁺ ion bombardment according to some embodiments. The diagram, 800, includes a target, 802, and a magnet assembly consisting of N-pole, 804, and S-pole, 806. The magnet assembly may be stationary or may rotate around a center axis, 816. Permanent magnets having a ring shape have been illustrated in FIG. 8. However, those skilled in the art will understand that any suitable arrangement of permanent magnets may be used. Furthermore, those skilled in the art will understand that electromagnets may also be used. As illustrated, the target is a multi-piece target including three sectors, Target Sector A, Target Sector B, and Target Sector C. Although three targets sectors are illustrated in FIG. 8, those skilled in the art will understand that any number of sectors may be used. As discussed previously, the target sectors may include the same material or may be formed from different materials. A slight gap between side surfaces of different sectors will be formed and is illustrated in the figure. To aid in the visualization, a single magnetic field line, 808, has been indicated. The shape of the magnetic field line has been exaggerated to facilitate the discussion below. The electric field (i.e. E) is formed between the substrate (not shown) and the target surface. Generally, the electric field is perpendicular to the target surface. The resultant force, F, acting on an Ar⁺ ion is illustrated resulting from the interaction of the ion with the electric field, E, and the magnetic field, B.

Two examples of the resultant force, F, acting on an Ar⁺ ion are illustrated resulting from the interaction of the ion with the electric field, E, and the magnetic field, B. As discussed with respect to FIG. 7 and the first example, the force, F, acting on Ar⁺ ions located approximately midway between the poles of the magnets will have a large lateral component (i.e. parallel to the target surface). This is illustrated by the “flat” portion of the magnetic field line indicated at 812. Note that this portion of the magnetic field lines is between the poles of the magnets. Ar⁺ ions that are subjected to this force will strike the target at off-angles that are not perpendicular to the target surface. This will result in the erosion of the corners of the various target sectors. As the target is used and the thickness of the various target sectors decreases, the erosion at the edges of the sectors will tend to widen the gap slightly.

In the second example, the force, F, acting on Ar⁺ ions located under the poles of the magnets (e.g. the force is aligned with the central axis of the magnet) will have a small lateral component (i.e. parallel to the target surface). As used herein, the “central axis” of the magnet will be understood to mean the longitudinal axis running through the two poles of the magnet. This is illustrated by the “vertical” portion of the magnetic field line indicated at 814. Note that this portion of the magnetic field lines is under the poles of the magnet and aligned with the central axis of the magnet. Ar⁺ ions that are subjected to this force will strike the target at angles that are approximately perpendicular to the target surface. If the gaps formed between the sectors of the target are aligned with the poles of the magnets, then the Ar⁺ ions have a higher probability of passing through the gap and striking the target backing material. The target backing material will be sputtered and will contaminate the deposited layer. As the target is used and the thickness of the various target sectors decreases, the gap will tend to widen, leading to increased contamination.

In some embodiments, the target sectors and the magnetron are designed so that the gaps between the target sectors do not align with the poles of the magnets (e.g. are not aligned with the central axis of the magnet). That is, the magnets of the magnet assembly that makes up the magnetron are aligned with one of the target sectors. This configuration reduces the number of Ar⁺ ions that impact the target at angles that are approximately perpendicular to the target surface and aligned with the gaps between the target sectors. This configuration increases the number of Ar⁺ ions that impact the target at off-angles that are not perpendicular to the target surface and not aligned with the gaps between the target sectors. As used herein, “not aligned” will be defined as a mis-alignment between the gaps and the magnet poles such that a substantial portion (i.e. more than 70%) of the ions impacting the target at the plurality of gaps arrive at angles greater than 10 degrees measured from a reference that is perpendicular to the surface of the target. This configuration reduces the contamination due to the sputtering of the target backing material throughout the life of the target. In some embodiments, the poles of the magnets are off-set from the gaps by at least a quarter of the gap between the N- and S-poles.

FIG. 8 illustrates a planar target and a planar magnetron. Those skilled in the art will understand that the discussion with respect to ensuring that the gaps between the different sectors of the target are not aligned with the poles of the magnets also applies to rotating cathodes (e.g. cylindrical targets) typically used in in-line sputtering systems used to deposit films on large area substrates.

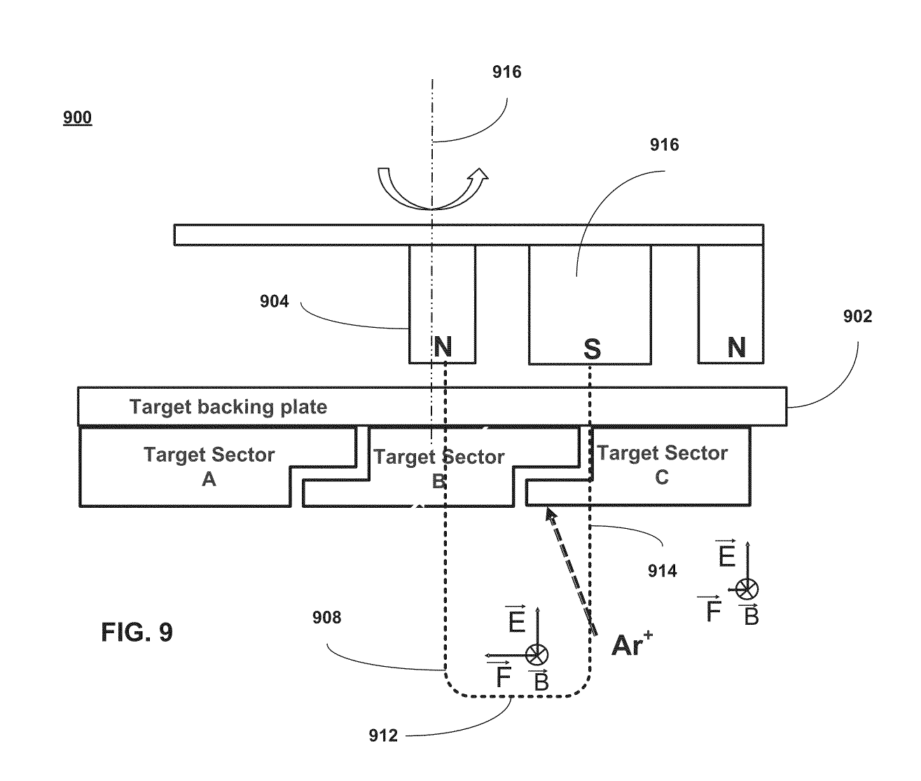

FIG. 9 is a schematic diagram illustrating the exploitation of the horizontal component of the Lorentz force to facilitate off-angle Ar⁺ ion bombardment according to some embodiments. The target configuration illustrated in FIG. 9 uses an “overlapping tile” configuration of a multi-piece target. In this configuration, the sectors of the target are manufactured to form interlocking pairs (e.g. edges of adjacent sectors of the target overlap). This is an additional step taken to prevent the sputtering of the backing plate materials. However, those skilled in the art will understand that the present disclosure can also be applied to this target configuration.

The diagram, 900, includes a target, 902, and a magnet assembly consisting of N-pole, 904, and S-pole, 906. The magnet assembly may be stationary or may rotate around a center axis, 916. Permanent magnets having a ring shape have been illustrated in FIG. 9. However, those skilled in the art will understand that any suitable arrangement of permanent magnets may be used. Furthermore, those skilled in the art will understand that electromagnets may also be used. As illustrated, the target is a multi-piece, overlapping tile target including three sectors, Target Sector A, Target Sector B, and Target Sector C. Although three targets sectors are illustrated in FIG. 9, those skilled in the art will understand that any number of sectors may be used. As discussed previously, the target sectors may include the same material or may be formed from different materials. A slight gap between side surfaces of different sectors will be formed and is illustrated in the figure. To aid in the visualization, a single magnetic field line, 908, has been indicated. The shape of the magnetic field line has been exaggerated to facilitate the discussion below. The electric field (i.e. E) is formed between the substrate (not shown) and the target surface. Generally, the electric field is perpendicular to the target surface. The resultant force, F, acting on an Ar⁺ ion is illustrated resulting from the interaction of the ion with the electric field, E, and the magnetic field, B.

Two examples of the resultant force, F, acting on an Ar⁺ ion are illustrated resulting from the interaction of the ion with the electric field, E, and the magnetic field, B. As discussed with respect to FIG. 7 and the first example, the force, F, acting on Ar⁺ ions located approximately midway between the poles of the magnets will have a large lateral component (i.e. parallel to the target surface). This is illustrated by the “flat” portion of the magnetic field line indicated at 912. Note that this portion of the magnetic field lines is between the poles of the magnets. Ar⁺ ions that are subjected to this force will strike the target at off-angles that are not perpendicular to the target surface. This will result in the erosion of the corners of the various target sectors. As the target is used and the thickness of the various target sectors decreases, the erosion at the edges of the sectors will tend to widen the gap slightly.

In the second example, the force, F, acting on Ar⁺ ions located under the poles of the magnets will have a small lateral component (i.e. parallel to the target surface). This is illustrated by the “vertical” portion of the magnetic field line indicated at 914. Note that this portion of the magnetic field lines is under the poles of the magnet. Ar⁺ ions that are subjected to this force will strike the target at angles that are approximately perpendicular to the target surface. If the gaps formed between the sectors of the target are aligned with the poles of the magnets, then the Ar⁺ ions have a higher probability of passing through the gap and striking the target backing material. The target backing material will be sputtered and will contaminate the deposited layer. As the target is used and the thickness of the various target sectors decreases, the gap will tend to widen, leading to increased contamination.

In some embodiments, the target sectors and the magnetron are designed so that the gaps between the target sectors do not align with the poles of the magnets. That is, the magnets of the magnet assembly that makes up the magnetron are aligned with one of the target sectors. This configuration reduces the number of Ar⁺ ions that impact the target at angles that are approximately perpendicular to the target surface and aligned with the gaps between the target sectors. In some embodiments, a central axis of the magnets that form the magnetron is aligned with the sectors of the target and “not aligned” with the gaps between the sectors of the target. As used herein the “central axis of the magnet” will be understood to mean the longitudinal axis running through the north pole and the south pole of the magnet. This configuration increases the number of Ar⁺ ions that impact the target at off-angles that are not perpendicular to the target surface and not aligned with the gaps between the target sectors. As used herein, “not aligned” will be defined as a mis-alignment between the gaps and the magnet poles such that a substantial portion (i.e. more than 70%) of the ions impacting the target at the plurality of gaps arrive at angles greater than 10 degrees measured from a reference that is perpendicular to the surface of the target. This configuration reduces the contamination due to the sputtering of the target backing material throughout the life of the target. In some embodiments, the poles of the magnets are off-set from the gaps by at least a quarter of the gap between the N- and S-poles.

FIG. 9 illustrates a planar target and a planar magnetron. Those skilled in the art will understand that the discussion with respect to ensuring that the gaps between the different sectors of the target are not aligned with the poles of the magnets also applies to rotating cathodes (e.g. cylindrical targets) typically used in in-line sputtering systems used to deposit films on large area substrates.

Although the foregoing examples have been described in some detail for purposes of clarity of understanding, the invention is not limited to the details provided. There are many alternative ways of implementing the invention. The disclosed examples are illustrative and not restrictive.

What is claimed:

1. An apparatus for sputtering, the apparatus comprising:
a power source operable to generate ions;
a target having a surface,
wherein the target is comprised of a plurality of sectors,
wherein each sector of the plurality of sectors are separated from each other by a plurality of gaps;
a magnetron,
wherein the magnetron comprises a magnet assembly,
wherein the magnet assembly comprises a plurality of magnets;
wherein each of the magnets is aligned with at least one of the plurality of sectors;
wherein the alignment is configured such that a substantial portion of ions impacting the target at the plurality of gaps arrive at angles greater than 10 degrees, the angle measured from a reference that is perpendicular to the surface of the target.

2. The apparatus of claim 1 wherein the magnet assembly comprises permanent magnets.

3. The apparatus of claim 2 wherein the magnet assembly can rotate around a center axis of the magnet assembly.

4. The apparatus of claim 2 wherein the magnet assembly is formed in a ring shape.

5. The apparatus of claim 1 wherein the magnet assembly comprises electromagnets.

6. The apparatus of claim 5 wherein the magnet assembly can rotate around a center axis of the magnet assembly.

7. The apparatus of claim 1 wherein the target is a planar target.

8. The apparatus of claim 1 wherein the target is a cylindrical target.

9. The apparatus of claim 1 wherein edges of adjacent sectors of the target overlap.

10. The apparatus of claim 1 wherein each of the multiple sectors of the target are formed from a material comprising one of a metal, a semiconductor, a metal oxide, a metal nitride, a metal oxynitride, a metal silicide, a metal boride, a metal sulfide, a metal selenide, a metal telluride, or a metal carbide.

11. The apparatus of claim 10 wherein the multiple sectors of the target comprise a same material.

12. The apparatus of claim 10 wherein the multiple sectors of the target comprise a different material.

13. The apparatus of claim 1 wherein the multiple sectors of the target are formed in a shape comprising one of pie-shaped sectors, annular rings, square tiles, or hexagonal tiles.
